(19) United States
(12) Patent Application Publication
(10) Pub. No.: US 2006/0255686 A1
(43) Pub. Date: Nov. 16, 2006

(54) Ultrasonic probe

(75) Inventor: Koetsu Saito, Tokyo (JP)

Correspondence Address: PEARNE & GORDON LLP, 1801 EAST 9TH SRTEET, SUITE 1200, CLEVELAND, OH, 44114-3108, US

(73) Assignee: Matsushit Electric Industrial Co., Ltd, Kadoma-shi, Osaka (JP)

(21) Appl. No.: 10/572,145

(22) PCT Filed: Sep. 17, 2004
(86) PCT No.: PCT/JP04/14009

§ 371 Date: Mar. 14, 2006

(30) Foreign Application Priority Data
Sep. 19, 2003 (JP) 2003-327388

(51) Int. Cl. H01L 41/08

(52) U.S. Cl. 310/322

(57) ABSTRACT

Disclosed is a technique of setting an ultrasonic wave directivity at a desired characteristic in accordance with position in a direction perpendicular to an arraying direction of piezoelectric elements. According to this technique, in a structure in which piezoelectric elements 1 are arrayed in a Y direction and each of the piezoelectric elements 1 is divided in a direction X perpendicular to the arraying direction Y, the width W of each of the piezoelectric elements 1 in the arraying direction is set at a minimum value at a central portion forming a position in the direction X perpendicular to the arraying direction Y while it is made wider toward both end portions, thus setting an ultrasonic directivity at a desired characteristic according to position in the X direction.

### TECHNICAL FIELD

The present invention relates to an ultrasonic probe for use in ultrasonic diagnostic equipment and other apparatus.

### BACKGROUND ART

As FIG. 21 shows, in a conventional ultrasonic probe, a plurality of piezoelectric elements 91 are arrayed in a Y-direction for transmission and reception of ultrasonic waves and a backing load member 92 is provided on the backs of the piezoelectric elements 91 for the attenuation of unnecessary ultrasonic waves transmitted from the piezoelectric elements 91 and further for holding the piezoelectric elements 91 mechanically. In addition, the thickness of each of the piezoelectric elements 91 at a position in an X-direction perpendicular to the arraying direction Y is made thinner in the vicinity of the center thereof while being made thicker toward both the end portions thereof so that each of the piezoelectric elements 91 has a curved configuration uneven in thickness. The variation of thickness of each of the piezoelectric elements 91 according to position in the X-direction develops characteristics which lengthens the depth of focus of an ultrasonic beam and provides a broadband frequency characteristic for the improvement of resolution (for example, see the following patent document 1).

Patent Document 1: Japanese Patent Application Publication No. HEI 7-107595 (FIGS. 7 and 18)

### DISCLOSURE OF THE INVENTION

However, the structure of the above-mentioned conventional ultrasonic probe creates the following problems. When a position in each of the piezoelectric elements 91 in the X-direction is in the vicinity of the central portion thereof, the thickness of the piezoelectric element 91 is made thinner and, hence, the transmission/reception of an ultrasonic wave with a high-frequency component takes place while, since the thickness thereof is made thicker toward the both end portions thereof, the transmission/reception of an ultrasonic wave with a low-frequency component takes place. On the other hand, the widths of the piezoelectric elements 91 in the arraying direction Y do not vary with respect to the X-direction.

Accordingly, with the structure in which the thickness of each of the piezoelectric elements 91 becomes thinner at a central position thereof in the X-direction so that the frequency becomes high and becomes thicker toward both the end portions thereof so that the frequency becomes lower, the directivity of an ultrasonic wave from the piezoelectric elements 91 becomes higher at the central portion providing a high frequency and becomes lower at both the end portions providing a lower frequency. With respect to the arraying direction Y of the piezoelectric elements 91, since phase control is implemented by carrying out electronic delays with respect to the plurality of piezoelectric elements 91 so as to focus or deflect an ultrasonic beam, a low ultrasonic wave directivity is desirable for obtaining a high-resolution ultrasonic image.

There is a problem which arises with the conventional structure, however, in that, since the central portion forming a position in each of the piezoelectric elements 91 in the X-direction shows a high directivity, the phase-controllable range becomes small, which makes it difficult to obtain an ultrasonic image with a high resolution. In addition, for lowering the directivity in the vicinity of the central portion forming an X-direction position where the frequency is high (for widening a predetermined sensitivity angle range), the array of the piezoelectric elements 91 can be made narrower to the high frequency at the central portion. However, this structure causes each of the piezoelectric elements 91 to have a larger thickness at both the end portions so that its column becomes high, whereupon an extreme difficulty arises in manufacturing.

The present invention has been developed with a view to solving the above-mentioned problems, and it is an object of the invention to provide an ultrasonic probe capable of realizing a desired ultrasonic wave directivity at each of positions in a direction perpendicular to an arraying direction of piezoelectric elements, thus lowering the ultrasonic wave directivity, carrying out phase-control through the use of an array of a large number of piezoelectric elements without restraint, narrowing an ultrasonic beam down, deflecting an ultrasonic beam, and obtaining an ultrasonic image with a high resolution.

For achieving this purpose, an ultrasonic probe according to the present invention comprises a plurality of piezoelectric elements arrayed in one direction for transmission and reception of ultrasonic waves and directivity setting means for setting different ultrasonic wave directivities according to a position in a direction perpendicular to the arraying direction of the piezoelectric elements.

This structure can provide a desired characteristic in ultrasonic wave directivity according to position in a direction perpendicular to the piezoelectric element arraying direction, which permits the phase control to be implemented through the use of the array of many piezoelectric elements without restraint, and enables narrowing down and deflecting an ultrasonic beam, thus producing an ultrasonic probe capable of offering an ultrasonic image with a high resolution.

In addition, the ultrasonic probe according to the present invention comprises division grooves for dividing each of the piezoelectric elements into a plurality of sections so that the divided sections are disposed side by side to stand in line along the direction perpendicular thereto.

This structure can provide a desired characteristic in ultrasonic wave directivity according to position in a direction perpendicular to the piezoelectric element arraying direction, which permits the phase control through the use of the array of many piezoelectric elements without restraint, and enables an ultrasonic beam to be narrowed down and deflected, thus producing an ultrasonic probe capable of offering an ultrasonic image with a high resolution.

Still additionally, the ultrasonic probe according to the present invention is characterized in that the directivity setting means is made such that a width of each of the piezoelectric elements in the arraying direction is made to have a minimum value at a central portion forming a position in the direction perpendicular thereto and is made to increase toward both end portions thereof.

This structure can lower the ultrasonic wave directivity (widen a predetermined sensitivity angle range) according to position in the direction perpendicular to the piezoelectric element arraying direction, which permits the phase control through the use of the array of many piezoelectric elements without restraint, and enables an ultrasonic beam to be narrowed down and deflected, thus producing an ultrasonic probe capable of providing an ultrasonic image with a high resolution.

Yet additionally, the ultrasonic probe according to the present invention is characterized in that the width of each of the piezoelectric elements is made to increase continuously as a position in the direction perpendicular thereto shifts from the central portion to both the end portions.

This structure can lower the ultrasonic wave directivity according to position in the direction perpendicular to the piezoelectric element arraying direction, which permits the phase control through the use of the array of many piezoelectric elements without restraint, and enables an ultrasonic beam to be narrowed down and deflected, thus producing an ultrasonic probe capable of providing an ultrasonic image with a high resolution.

Moreover, the ultrasonic probe according to the present invention is characterized in that the width of each of the piezoelectric elements is made to increase stepwise as a position in the direction perpendicular thereto shifts from the central portion to both the end portions.

This structure can lower the ultrasonic wave directivity according to position in the direction perpendicular to the piezoelectric element arraying direction, which permits the phase control through the use of the array of many piezoelectric elements without restraint, and enables an ultrasonic beam to be narrowed down and deflected, thus producing an ultrasonic probe capable of providing an ultrasonic image with a high resolution.

Still moreover, the ultrasonic probe according to the present invention is characterized in that one or more acoustic matching layers are formed on each of the piezoelectric elements, and the directivity setting means is made such that the number of divisions made in the acoustic matching layer in the arraying direction stands at a maximum at its central portion forming a position in the direction perpendicular thereto and the number of divisions in the arraying direction decreases as the position in the direction perpendicular thereto shifts to both the end portions.

This structure can lower the ultrasonic wave directivity according to position in the direction perpendicular to the piezoelectric element arraying direction, which permits the phase control through the use of the array of many piezoelectric elements without restraint, and enables an ultrasonic beam to be narrowed down and deflected, thus producing an ultrasonic probe capable of providing an ultrasonic image with a high resolution.

Yet moreover, the ultrasonic probe according to the present invention is characterized in that a thickness T of each of the piezoelectric elements varies according to position in the direction perpendicular thereto, and the directivity setting means is made such that the ratio W/T between a width W of the piezoelectric element and the thickness T thereof falls within a predetermined range as the position in the perpendicular thereto shifts from the central portion to both the end portions.

This structure can lower the ultrasonic wave directivity according to position in the direction perpendicular to the piezoelectric element arraying direction, which permits the phase control through the use of the array of many piezoelectric elements without restraint, and enables an ultrasonic beam to be narrowed down and deflected, thus producing an ultrasonic probe capable of providing an ultrasonic image with a high resolution.

In addition, the ultrasonic probe according to the present invention is characterized in that the ratio W/T between the width W and the thickness T continuously or step wise falls within the predetermined range as the position in the perpendicular thereto shifts from the central portion to both the end portions.

This structure can achieve a broadband frequency characteristic and a high sensitivity, and can lower the ultrasonic wave directivity, which permits the phase control through the use of the array of many piezoelectric elements without restraint, and enables an ultrasonic beam to be narrowed down and deflected, thus producing an ultrasonic probe capable of providing an ultrasonic image with a high resolution.

Still additionally, the ultrasonic probe according to the present invention is characterized in that the thickness of each of the plurality of piezoelectric elements is made equally irrespective of position in the direction perpendicular thereto.

With this structure, the plurality of piezoelectric elements are arrayed in one direction and divided in a direction perpendicular to the arraying direction and, even in a case in which the thickness thereof is set to have an equal value irrespective of the position in the direction perpendicular thereto, it is possible to lower the ultrasonic wave directivity in accordance with a position in the direction perpendicular to the piezoelectric element arraying direction, which permits the phase control to be executed freely through the use of the array of many piezoelectric elements for narrowing the ultrasonic beam down and deflecting the ultrasonic beam, thus providing an ultrasonic probe which can produce an ultrasonic image with a high resolution.

Yet additionally, the ultrasonic probe according to the present invention is characterized in that the directivity setting means is designed such that the directivity of the ultrasonic probe is set at the lowest directivity at a central portion which forms a position in the direction perpendicular thereto while it is set to become higher as the position in the direction perpendicular thereto shifts to both the end portions thereof.

This structure can lower the ultrasonic wave directivity according to a position in the direction perpendicular to the piezoelectric element arraying direction, which permits the phase control to be executed freely through the use of the array of many piezoelectric elements for narrowing the ultrasonic beam down and deflecting the ultrasonic beam, thus providing an ultrasonic probe which can produce an ultrasonic image with a high resolution.

Moreover, the ultrasonic probe according to the present invention is characterized in that the transmission/reception frequency of the piezoelectric elements is set at the highest frequency at the central portion which forms a position in the direction perpendicular thereto while it is set to become lower as the position in the direction perpendicular thereto shifts to both the end portions thereof.

With this structure, the frequency at the central portion forming a position in the piezoelectric elements in the direction perpendicular thereto shows the highest value and, even when the frequency thereof becomes lower as the position shifts to both the end portions, the ultrasonic directivity in the direction perpendicular to the piezoelectric element arraying direction can be set to have a low value. Accordingly, the phase control is executable freely through the use of the array of many piezoelectric elements, and the ultrasonic beam can be narrowed down and deflected, thus providing an ultrasonic probe which can produce an ultrasonic image with a high resolution.

According to the present invention, since the ultrasonic wave directivity can be set at a desired characteristic in accordance with a position in a direction perpendicular to the piezoelectric element arraying direction, the phase control is executable freely through the use of the array of many piezoelectric elements, and the ultrasonic waves can be narrowed down and deflected, thereby providing an ultrasonic probe which can produce an ultrasonic image with a high resolution.

### BRIEF DESCRIPTION OF THE DRAWINGS

FIG. 1 is a top view schematically showing an ultrasonic probe according to first and fourth embodiments of the present invention;

FIG. 2 is a side cross-sectional view taken along a line A-A′ in FIG. 1;

FIG. 3 is a top view schematically showing an ultrasonic probe according to a second embodiment of the present invention;

FIG. 4 is a side cross-sectional view taken along a line B-B′ in FIG. 3;

FIG. 5 is a top view schematically showing an ultrasonic probe according to a third embodiment of the present invention;

FIG. 6 is a side cross-sectional view of FIG. 5;

FIG. 7 is a side cross-sectional view taken along a line C-C′ in FIG. 5;

FIG. 8 is a side cross-sectional view taken along a line D-D′ in FIG. 5;

FIG. 9 is a top view schematically showing an ultrasonic probe according to a fifth embodiment of the present invention;

FIG. 10 is a side cross-sectional view of FIG. 5;

FIG. 11 is a top view schematically showing an ultrasonic probe according to sixth and ninth embodiments of the present invention;

FIG. 12 is a side cross-sectional view taken along a line A-A′ in FIG. 11;

FIG. 13 is a top view schematically showing an ultrasonic probe according to a seventh embodiment of the present invention;

FIG. 14 is a side cross-sectional view taken along a line B-B′ in FIG. 13;

FIG. 15 is a top view schematically showing an ultrasonic probe according to an eighth embodiment of the present invention;

FIG. 16 is a side cross-sectional view of FIG. 15;

FIG. 17 is a side cross-sectional view taken along a line C-C′ in FIG. 15;

FIG. 18 is a side cross-sectional view taken along a line D-D′ in FIG. 15;

FIG. 19 is a top view schematically showing an ultrasonic probe according to a tenth embodiment of the present invention;

FIG. 20 is a side cross-sectional view taken along a line E-E′ in FIG. 19; and

FIG. 21 is a perspective view schematically showing a conventional ultrasonic probe.

### BEST MODE FOR CARRYING OUT THE INVENTION

### First Embodiment

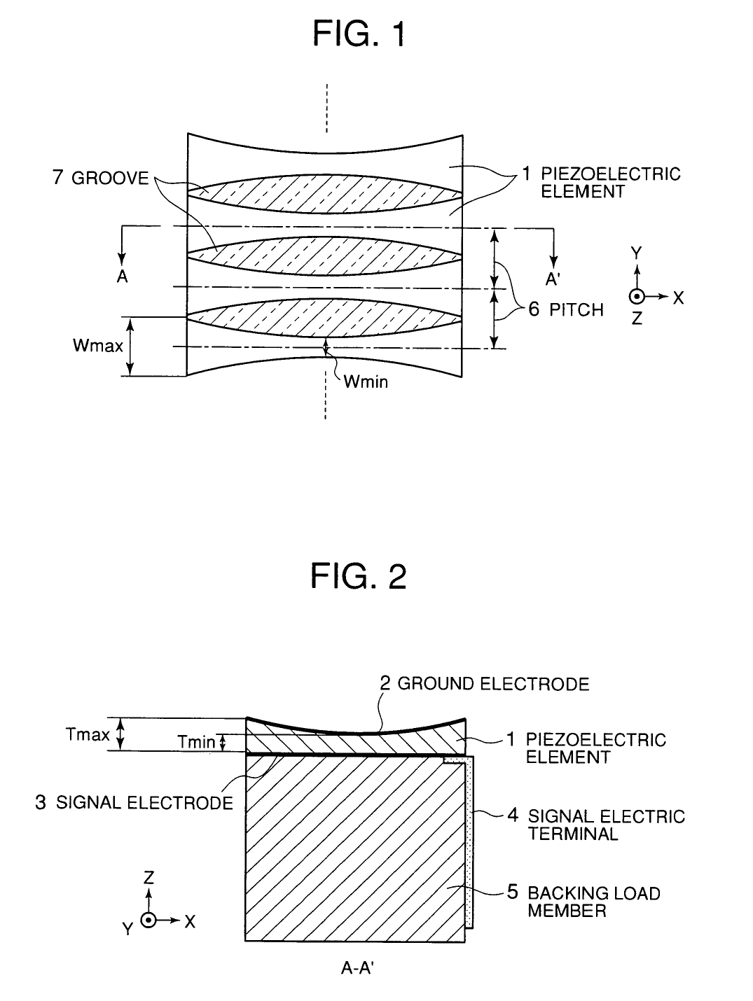

Ultrasonic probes according to embodiments of the present invention will be described hereinbelow with reference to the drawings. An ultrasonic probe according to a first embodiment of the present invention is shown in FIGS. 1 and 2. FIG. 1 is a top view and FIG. 2 is a side cross-sectional view taken along a line A-A′ in FIG. 1.

In FIGS. 1 and 2, this ultrasonic probe is made up of a plurality of piezoelectric elements 1 arrayed or arranged in a Y-direction for transmission/reception of ultrasonic waves in a Z-direction, a common ground electrode 2 provided on top surfaces of the piezoelectric elements 1, a plurality of signal electrodes 3 each provided on a base of each of the piezoelectric elements 1, a plurality of signal electric terminals 4 each for fetching a signal from each of the signal electrodes 3, and a backing load member 5 having a function to mechanically hold the backs of the piezoelectric elements 1 and further to attenuate an unnecessary ultrasonic signal when needed. The piezoelectric elements 1 are made of a piezoelectric ceramic such as PZT-based material, monocrystal or the like. The ground electrode 2 and the signal electrodes 3 are formed on the top surfaces and backs of the piezoelectric elements 1 in such a manner as to deposit or sputter gold or silver or to bake silver.

In FIG. 1, a pitch 6 between the piezoelectric elements 1 adjacent to each other in the arraying direction Y is determined as needed. For example, in the case of a so-called phased array probe type made to electronically deflect an ultrasonic beam through phase control, the number of piezoelectric elements 1 to be arrayed is 64 to 128 and, in view of the occurrence angle of grating lobe, in general, the pitch 6 between the adjacent piezoelectric elements 1 is half a wavelength and, in a case in which the sound velocity of a medium like a living body is 1.54 km/s at a frequency of 2.5 MHz, the pitch 6 becomes 0.308 mm.

Moreover, each of grooves 7 is formed between the piezoelectric elements 1 adjacent to each other such that the width W of each of the piezoelectric elements 1 in the arraying direction Y shows a minimum value Wmin in the vicinity of a central portion forming a position in the piezoelectric element 1 in the X-direction, and it becomes gradually larger as the position shifts to each of both its end portions and has a maximum value Wmax at both the end portions thereof. When the width W of the piezoelectric element 1 in the arraying direction Y is made to show different values according to position therein in the X-direction, the directivity can easily be changed from the relationship among the width W, the frequency and the directivity.

Accordingly, inversely with the width W of the piezoelectric element 1, the width of the groove 7 formed between the adjoining piezoelectric elements 1 becomes wider in the vicinity of the central portion and it becomes narrower toward both the end portions. For making the adjoining piezoelectric elements 1 acoustically oscillate independently of each other, it is desirable that the groove 7 shows a large difference in acoustic impedance with respect to the piezoelectric element 1. Although a gas (air) is ideal, in view of stabilizing the piezoelectric element 1 and holding it against mechanical impacts, the groove 7 is actually filled with a material such as silicone rubber or polyurethane rubber, or a material produced by mixing an inorganic material or a powder of an inorganic matter thereinto. Among available methods of making a structure so that the width W of the piezoelectric element 1 has different values according to position in the X-direction, there are a processing method based on a combination of laser beam and chemical etching and a processing method using sand blast or the like in a state where a patterned mask is put on the piezoelectric element 1.

FIG. 2 is a cross-sectional view taken along a line A-A′ in FIG. 1, where the thickness T of the piezoelectric element 1 in the Z-direction takes a different value according to position in the X-direction. In this example, the thickness T of the piezoelectric element 1 in the vicinity of its central portion is set at a minimum value (Tmin) while the thickness thereof becomes larger toward both its end portions so that the thickness takes a maximum value (Tmax) at both the end portions, thus forming a curved configuration. With respect to the minor-axis direction X of the plurality of piezoelectric elements 1 arranged in the Y-direction, the central portion of the piezoelectric element 1, which has the thinnest thickness T, enables the transmission/reception at a high frequency component while, since the piezoelectric element 1 becomes thicker toward both the end portions, the transmission/reception can be made at a lower frequency component, thereby lengthening the depth of focus of an ultrasonic beam and providing a broadband frequency characteristic.

On the other hand, when, with respect to the plurality of piezoelectric elements 1 arranged in the Y-direction, each of the piezoelectric elements 1 is electronically delayed so as to implement phase control for deflecting an ultrasonic beam, the directivity of the piezoelectric element 1 greatly affects the performance. That is, in the case of the phase control, the degree of freedom of the phase control increases as the direcrtivity of each of the piezoelectric elements 1 decreases and, hence, the lower directivity thereof is desirable. As commonly well-known, a directivity factor representative of this directivity is calculated according to the following equation.
Re(θ)=sin(π·a·sin θ/λ)/(π·a·sin θ/λ) (1)
where ”a” designates a width W of the piezoelectric element 1, and λ depicts a wavelength (sound velocity of a medium/frequency). As seen from the above-mentioned equation, the directivity factor Re(θ) tends to decrease as the width W of the piezoelectric element 1, i.e., as a becomes smaller and to increase as the frequency becomes higher.

This ultrasonic probe 1 is made such that, when an electric signal is applied from a main body of ultrasonic diagnostic equipment or the like through the signal electric terminals 4 and the ground electric terminal (not shown) drawn from the ground electrode 2, the piezoelectric elements 1 mechanically oscillate so as to make the transmission and reception of ultrasonic waves. An ultrasonic probe for use in ultrasonic diagnostic equipment handling a living body as an object under inspection is a so-called sensor to be directly brought into contact with a living body or indirectly brought into contact therewith in a state where an ultrasonic wave propagation medium is interposed therebetween, so as to transmit ultrasonic waves into the living body and to again receive waves reflected from the living body so that the main body processes this signal and displays a diagnostic image on a monitor for diagnosis.

In this system, in general, the transmission/reception in each of the plurality of piezoelectric elements 1 arrayed in the Y-direction is time-delayed so as to implement the phase control so that an ultrasonic beam is focused at a desired position for achieving a high resolution, or an ultrasonic beam is deflected to carry out sector-like scanning. For example, in the structure shown in FIGS. 1 and 2, in a case in which piezoelectric ceramics corresponding to PZT-5H is used as the piezoelectric elements 1 to set the mean frequency of both the end portions at 2.5 MHz and set the mean frequency of the central portion at 5 MHz, with respect to the thickness T of the piezoelectric element 1, the central portion has a thickness of Tmin=approximately 0.3 mm from a material constant, while the thickness T thereof becomes gradually larger toward both the end portions so that both the end portions have a thickness of Tmax=approximately 0.6 mm.

On the other hand, with respect to the arraying direction Y, as mentioned above, when the pitch 6 is set on the basis of half the wavelength, because of the frequency=5 MHz, the width Wmin of the central portion of the piezoelectric element 1 becomes ½ of 1 wavelength (0.308 mm), i.e., Wmin=0.154 mm. The width of the piezoelectric element 1 increases gradually and continuously with respect to the width Wmin (curved configuration) toward both the end portions and the width Wmax reaches 0.308 mm at both the end portions because of the frequency=2.5 MHz. In the case of this structure, even if the frequency varies from the central portion to both the end portions, i.e., according to positions in the piezoelectric element 1 in the X-direction, the width W of the piezoelectric element 1 in the arraying direction Y takes a different value according to the position in the X-direction and, hence, the desired directional characteristics approximately equal to each other are securable at the central portion and at both the end portions.

In addition, the directional characteristic can be changed according to position in the X-direction by properly changing the width W of the piezoelectric element 1 in the arraying direction Y in accordance with position in the X-direction according to purpose (directivity setting means). Still additionally, a high frequency of the piezoelectric element 1 in the vicinity of its central portion forming a position in the X-direction tends to show a short distance (position where the depth is low) in an ultrasonic image and, preferably, the directional angle becomes larger with shorter distance and, hence, a lower directivity is desirable. For this reason, the width Wmin of the central portion is further decreased, which enables the central portion to have a lower directivity than that of both the end portions. Therefore, even a portion having a high frequency component in the vicinity of the central portion of the piezoelectric element 1 can be lowered in directivity, which permits the phase control to be freely executed through the use of many piezoelectric elements 1 arrayed and enables narrowing down (focusing) an ultrasonic beam and deflecting an ultrasonic beam, thus providing an ultrasonic probe which can produce an ultrasonic image with a high resolution.

Incidentally, although in the description of the first embodiment nothing is provided on the ground electrode 2 positioned on the top surface side of the piezoelectric element 1, the same effects are also attainable even in the case of a structure of an ultrasonic probe in which one or more acoustic matching layers are formed on the top surface of the ground electrode 2. Moreover, although in the description of the first embodiment a piezoelectric ceramics such as PZT or monocrystal is used as the piezoelectric elements 1, a structure of an ultrasonic probe employing, as the piezoelectric elements 1, a so-called composite piezoelectric material produced by combining a piezoelectric ceramics and an organic polymer can also provide the same effects.

### Second Embodiment

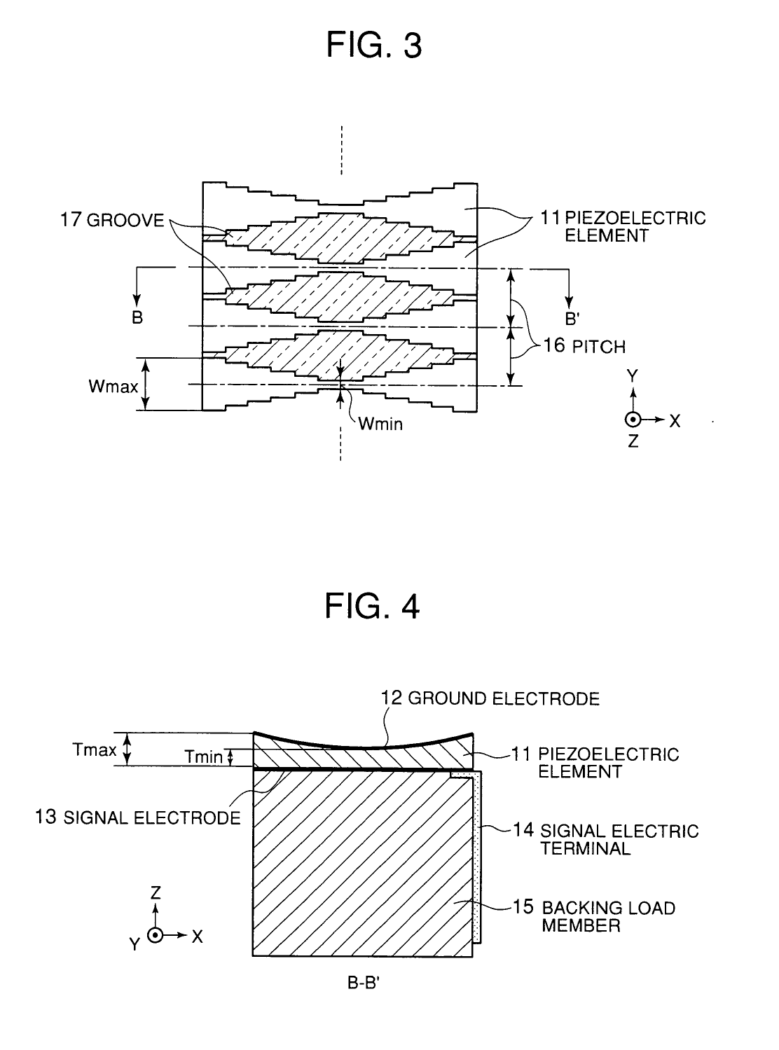

Furthermore, FIGS. 3 and 4 are illustrations of an ultrasonic probe according to a second embodiment of the present invention. In FIGS. 3 and 4, this ultrasonic probe is made up of a plurality of piezoelectric elements 11 arrayed in the Y-direction for transmission/reception of ultrasonic waves in the Z-direction, a common ground electrode 12 located on top surfaces of the piezoelectric elements 11, a plurality of signal electrodes 13 each provided on a back of each of the piezoelectric elements 11, a plurality of signal electric terminals 14 each for fetching a signal from each of the signal electrodes 13, and a backing load member 5 having a function to mechanically hold the backs of the piezoelectric elements 11 and further to attenuate an unnecessary ultrasonic signal when needed. The piezoelectric elements 11 are made of a piezoelectric ceramic such as PZT-based material, monocrystal or the like. The ground electrode 12 and the signal electrodes 13 are formed on the top surfaces and backs of the piezoelectric elements 11 in such a manner as to deposit or sputter gold or silver or to bake silver.

Moreover, in FIG. 3, a pitch 16 between the piezoelectric elements 11 adjacent to each other in the Y-direction is determined as needed as in the case of the first embodiment. For example, in the case of a so-called phased array probe type made to electronically deflect an ultrasonic beam through phase control, the number of piezoelectric elements 11 to be arrayed is commonly 64 to 128, and the pitch 16 is half a wavelength and, in a case in which the sound velocity of a medium is 1.54 km/s at a frequency of 2.5 MHz, the pitch 16 becomes 0.308 mm. In this case, a difference from the first embodiment is that the width W of the piezoelectric element 11 is set at a minimum width Wmin in the vicinity of the central portion forming a position in the X-direction and becomes stepwise wider toward both the end portions so that the width W of both the end portions becomes a maximum value Wmax.

FIG. 4 is a cross-sectional view taken along a line B-B′ in FIG. 3. The thickness T of the piezoelectric element 11 in the Z-direction varies according to position in the X-direction and, in this example, the thickness T of the vicinity of the piezoelectric element 11 is set at a minimum value Tmin and becomes larger toward both the end portions so as to reach a maximum value Tmax at both the end portions. It is also acceptable that the thickness T of the piezoelectric element 11 varies continuously or varies step wise. Thus, with respect to the minor-axis direction X of the piezoelectric element 11, the central portion at where the thickness T of the piezoelectric element 11 reaches a minimum value can transmit and receive a high frequency component and, since the thickness of the piezoelectric element increases toward both the end portions, the transmission/reception of a low frequency component is feasible, thus lengthening the depth of focus of an ultrasonic beam and attaining a broadband frequency characteristic.

On the other hand, as in the case of the above-described first embodiment, when, with respect to the piezoelectric elements 11 arranged in the Y-direction, an ultrasonic beam is deflected in a manner such that each of the piezoelectric elements 11 is electronically delayed to carry out the phase control, the directivity of the piezoelectric elements 11 greatly affects the performance. That is, for the phase control, a lower directivity of each of the piezoelectric elements 11 preferably increases the degree of freedom of the phase control. These operations of the ultrasonic probe are same as those in the first embodiment, and the description thereof will be omitted.

For example, in the structure shown in FIGS. 3 and 4, in a case in which piezoelectric ceramics corresponding to PZT-5H is used as the piezoelectric elements 11 to set the mean frequency of both the end portions at 2.5 MHz and set the mean frequency of the central portion at 5 MHz, as the thickness T of the piezoelectric element 11, the central portion has a thickness of Tmin=approximately 0.3 mm, while the thickness T thereof becomes gradually larger so that both the end portions have a thickness of Tmax=approximately 0.6 mm. On the other hand, with respect to the arraying direction Y, when the array pitch 16 is basically set at half the wave length as mentioned above, because of 5 MHz, the minimum width Wmin of the piezoelectric element 11 at its central portion becomes half as much as one wavelength=0.308, i.e., Wmin=0.154 mm.

As the position shifts from the portion having this width Wmin to both the end portions, for example, the frequency is symmetrically divided into 6 stages on one side (11 divisions in total at both sides) so that the width W of the piezoelectric element 11 becomes stepwise larger. Therefore, in a case in which the high frequency at the central portion is set at 5 MHz and the next frequencies are set at 4.5 MHz, 4 MHz, 3.5 MHz, 3 MHz and the frequency at both the end portions is set at 2.5 MHz, respectively, while the respective widths W are set at half the wavelength, the width W becomes 0.154 mm at 5 MHz, 0.171 mm at 4.5 MHz, 0.193 mm at 4 MHz, 0.22 mm at 3.5 MHz and 0.257 mm at 3 MHz, and both the end portions have a maximum width, i.e., Wmax=0.308 mm at 2.5 MHz.

With this structure, even if the frequency stepwise varies as the position in the X-direction shifts from the central portion to both the end portions, since the width W of the piezoelectric element 11 varies, with respect to the directivity according to the position in the piezoelectric element 11 in the X-direction, the directional characteristics approximately equal to each other are securable. Therefore, since even a portion with a high frequency in the vicinity of the central portion of the piezoelectric element 11 can be lowered in directivity, it is possible to carry out the phase control freely through the use of many piezoelectric elements 11 arrayed and to narrow down and deflect an ultrasonic beam, thus providing an ultrasonic probe which can produce an ultrasonic image with a high resolution.

Although in the description of the second embodiment nothing is provided on a top surface of the ground electrode 12, the same effects are also obtainable even in the case of a structure of an ultrasonic probe in which one or more acoustic matching layers are formed on the top surface of the ground electrode 12. Moreover, although in the description of the second embodiment a piezoelectric ceramics such as PZT or monocrystal is used as the piezoelectric elements 11, the same effects are also obtainable even in the case of a structure of an ultrasonic probe employing, as the piezoelectric elements 11, a so-called composite piezoelectric material produced by combining a piezoelectric ceramics and an organic polymer.

The stepwise change of the width W of the piezoelectric element 11 is more advantageous in manufacturing and cost than the continuous change of the width W thereof. Ideally, it is desirable that these steps are processed more finely to make a continuously varying type superior in performance.

### Third Embodiment

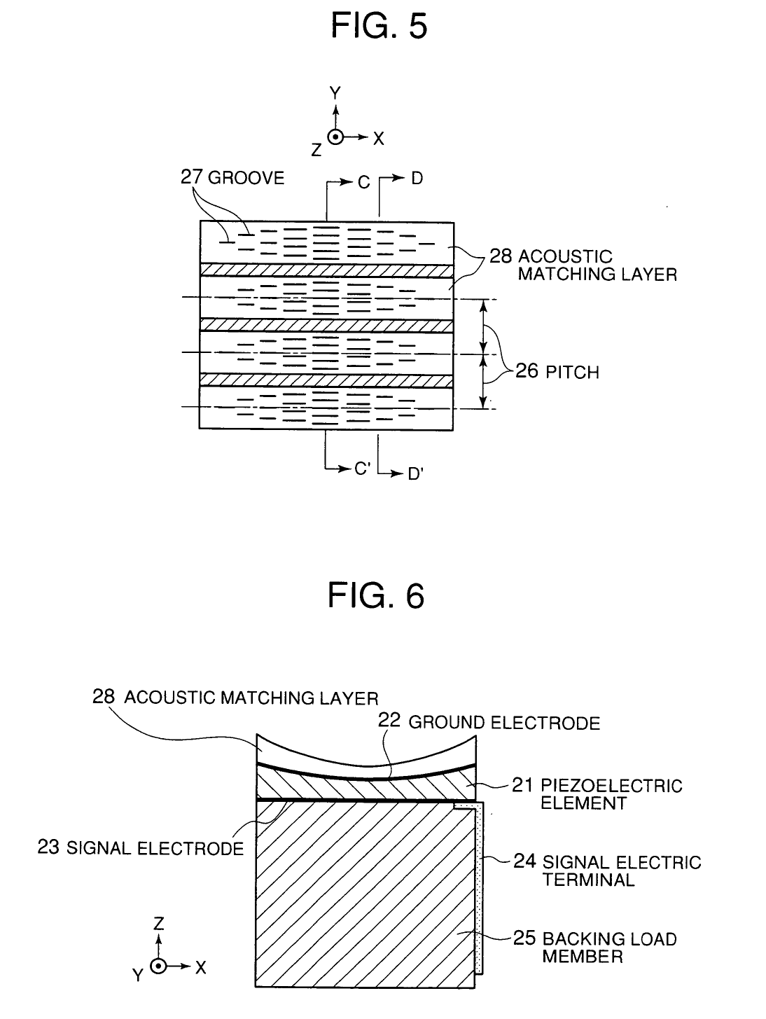

FIGS. 5 to 8 are illustrations of an ultrasonic probe according to a third embodiment of the present invention. This ultrasonic probe is made up of a plurality of piezoelectric elements 21 arrayed in the Y-direction for transmission/reception of ultrasonic waves in the Z-direction, a common ground electrode 22 located on top surfaces of the piezoelectric elements 21, acoustic matching layers 28 each formed as a one-or-more-layer structure (in this case, acoustic matching layers each formed as one layer), a plurality of signal electrodes 23 each provided on a back of each of the piezoelectric elements 21, a plurality of signal electric terminals 24 each for fetching a signal from each of the signal electrodes 23, and a backing load member 25 having a function to mechanically hold the backs of the piezoelectric elements 21 and further to attenuate an unnecessary ultrasonic signal when needed. The piezoelectric elements 21 are made of a piezoelectric ceramic such as PZT-based material, monocrystal or the like. The ground electrode 22 and the signal electrodes 23 are formed on the top surfaces and backs of the piezoelectric elements 21 in such a manner as to deposit or sputter gold or silver or to bake silver.

In this ultrasonic probe, the width W does not vary in the minor-axis direction X of the piezoelectric element 21 unlike the first and second embodiments, and the structure of each of the acoustic matching layers 28 differs from those in the first and second embodiments. That is, the acoustic matching layer 28 is divided into a plurality of areas in the minor-axis direction X. The number of divisions stands at 11, but it can properly be determined according to purpose. Moreover, in the acoustic matching layer 28, a central portion forming a position in the minor-axis direction X is divided into 6 sections by division grooves 27 in the arraying direction Y, and the number of divisions is stepwise decreased toward both the end portions.

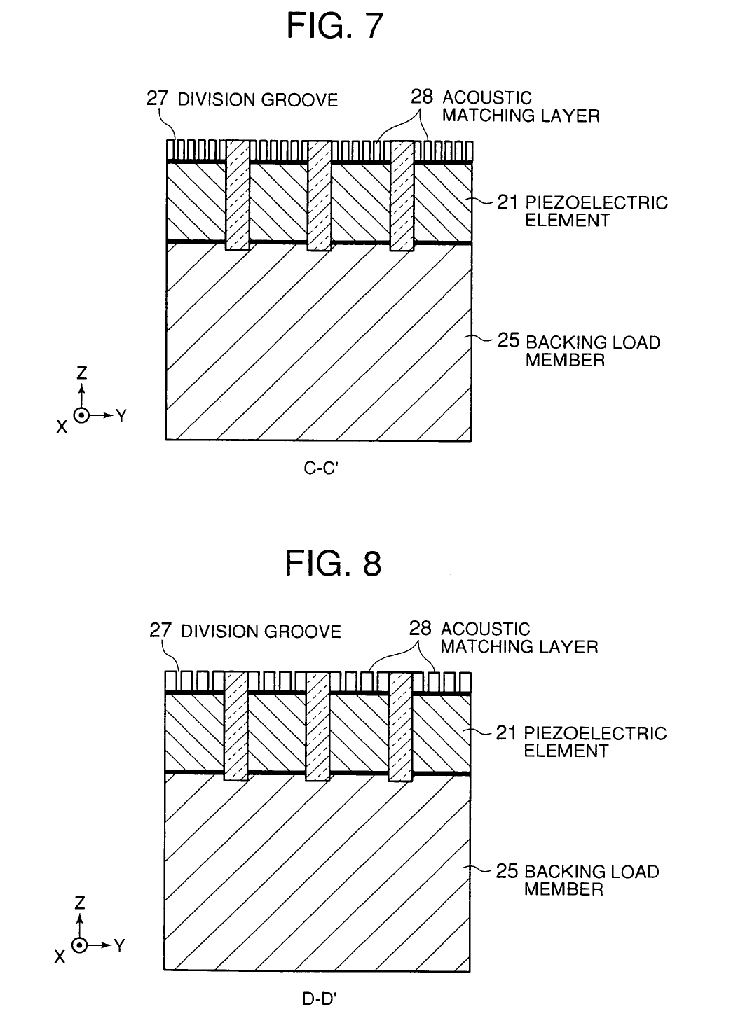

FIGS. 7 and 8 are cross-sectional views taken along lines C-C′ and D-D′ in FIG. 5, respectively, for explaining a structure of the division grooves 27 of the acoustic matching layer 28. FIG. 7 shows a central portion where the acoustic matching layer 28 is divided into 6 sections, and FIG. 8 shows a next-but-one portion with respect to the central portion, where it is divided into 4 sections. Although it is most desirable that the interiors of these division grooves 27 of the acoustic matching layer 28 are filled with air, if this makes it difficult to construct the ultrasonic probe, it is also acceptable to use a soft resin, for example, silicone rubber or polyurethane rubber, or a material produced by mixing a powder of an inorganic matter or the like thereinto. In this connection, it is also appropriate that the division grooves 27 to be made in the acoustic matching layer 28 are additionally made in a portion of each of the piezoelectric elements 21.

With the structure described above, when the transmission/reception of ultrasonic waves is made at a high frequency at the central portion forming a position in the piezoelectric element 21 in the X-direction and made at a lower frequency toward both the end portions, although the widths of the piezoelectric element 21 in the minor-axis direction X are equal to each other, the directivity is lowered because the number of divisions of the acoustic matching layer 28 is further increased at a portion generating a higher frequency. This utilizes the fact that, without the division of the piezoelectric element 21, the directivity can be lowered by dividing the acoustic matching layer 28 by means of a laser beam or an ultrasonic cutter. Therefore, this can solve a problem that a difference in directional characteristic exists between the central portion and both the end portions which form positions in the X-direction and the central portion has a higher directional characteristic.

That is, looking at the fact that the directivity of the ultrasonic probe has relation to the width of the piezoelectric element 21 and the width of the acoustic matching layer 28 or the number of divisions, the number of divisions of the acoustic matching layer 28 in the Y-direction is increased toward the center of the position in the X-direction so as to approach the point sound source, thereby lowering the directivity. In this embodiment, the central portion has a high directivity because it shows a high frequency and, for lowering this, the number of divisions at the central portion forming a position in the acoustic matching layer 28 in the X-direction is set at a maximum while the number of divisions of the acoustic matching layer 28 is stepwise decreased toward both the end portions, thereby attaining the directional characteristics nearly equal to each other.

Thus, since even a portion with a high frequency component in the vicinity of the positional center of the piezoelectric element 21 in the X-direction can be lowered in directivity, the phase control is freely executable through the use of many piezoelectric elements 21 arrayed and an ultrasonic beam can be narrowed down and deflected, which provides an ultrasonic probe which can produce an ultrasonic image with a high resolution.

Moreover, although in the description of the third embodiment a piezoelectric ceramics such as PZT or monocrystal is used as the piezoelectric elements 21, a structure of an ultrasonic probe employing, as the piezoelectric elements 21, a so-called composite piezoelectric material produced by combining a piezoelectric ceramics and an organic polymer can also provide the same effects. Still moreover, although in the description of the third embodiment the widths W of the piezoelectric element 21 in the arraying direction Y are made to be nearly equal to each other in the X-direction, the same effects are obtainable even in the case of a structure of an ultrasonic probe in which the width is made narrower at the central portion forming a position in the X-direction and is made wider toward both the end portions or in which a so-called composite piezoelectric material produced by combining a piezoelectric ceramics and an organic polymer is employed as the piezoelectric elements 21.

### Fourth Embodiment

Furthermore, referring to FIGS. 1 and 2, a description will be given hereinbelow of an ultrasonic probe according to a fourth embodiment of the present invention. The description of a structure according to the fourth embodiment will be omitted because it is the same as that of the first embodiment, while the description will be given of only an operation of the fourth embodiment.

In the fourth embodiment, in a case in which the thickness Tmin to Tmax of the piezoelectric element 1 and the width Wmin to Wmax take continuously different values, the ratio W/T of the width W of the piezoelectric element 1 and the thickness T thereof varies. On the other hand, the W/T of the piezoelectric element 1 is already well-known and, as an electromechanical coupling coefficient k of the piezoelectric element 1 becomes higher, the sensitivity increases, and the specific frequency band can be widened. This has great relation to the W/T and, in the case of a piezoelectric ceramic material corresponding to PZT-5H, the electromechanical coupling coefficient k shows a maximum value when the W/T is close to 0.5 to 0.6.

Accordingly, since the thickness T is at a minimum in the vicinity of the central portion forming a position in the piezoelectric element 1 in the X-direction, it is desirable that, in connection with this thickness, the width W is set so that the W/T becomes 0.5 to 0.6. Moreover, since the thickness T of the piezoelectric element 1 increases toward both the end portions, it is desirable that the width W is gradually made wider so that the W/T falls into a range of 0.5 to 0.6 as a value within a predetermined range. Thus, the electromechanical coupling coefficient k becomes the same in any region, which provides an excellent characteristic (frequency characteristic, sensitivity).

Moreover, for a type in which the thickness T of the piezoelectric element 1 is changed in the direction X perpendicular to the arraying direction Y so as to change the frequency, if the width W of the piezoelectric element 1 is equalized from the central portion to both the end portions, the W/T at the central portion forming a thin portion of the piezoelectric element 1 becomes higher. When the W/T exceeds 0.6, the oscillation occurs even in the width direction Y and, when the frequency thereof approaches the oscillation frequency in the thickness direction Z, adverse effects appear on the frequency characteristic. This embodiment is made to reduce the adverse influence of the oscillation frequency in the width direction Y.

With the structure described above, since not only even a portion with a high frequency component in the vicinity of the central portion forming a position in the piezoelectric element 1 in the X-direction can be lowered in directivity but also the electromechanical coupling coefficient k of the piezoelectric element 1 shows a high value and even the influence of the frequency of the width oscillation is reducible, a broad band frequency is obtainable together with a high sensitivity and an ultrasonic beam can be narrowed down, which can provide an ultrasonic probe capable of producing an ultrasonic image with a high resolution.

Although in the description of the fourth embodiment the thickness Tmin to Tmax of the piezoelectric element 1 and the width Wmin to Wmax thereof vary continuously, also in a case in which both the thickness Tmin to Tmax of the piezoelectric element 1 and the width Wmin to Wmax thereof are made to vary stepwise, or even when only the thickness T or only the width W is made to vary stepwise, the same effects are attainable.

### Fifth Embodiment

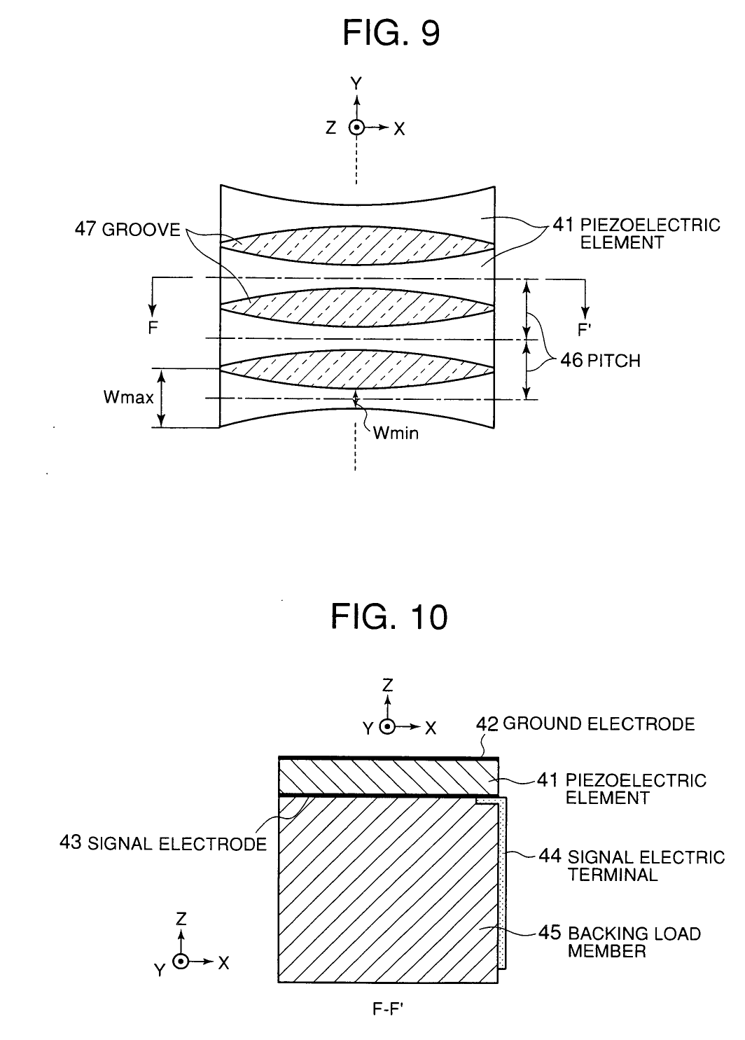

FIGS. 9 and 10 are illustrations of an ultrasonic probe according to a fifth embodiment of the present invention. In FIGS. 9 and 10, this ultrasonic probe is made up of a plurality of piezoelectric elements 41 arrayed in the Y-direction for transmission/reception of ultrasonic waves in the Z-direction, a common ground electrode 42 located on top surfaces of the piezoelectric elements 41, a plurality of signal electrodes 43 each provided on a back of each of the piezoelectric elements 41, a plurality of signal electric terminals 44 each for fetching a signal from each of the plurality of signal electrodes 43, and a backing load member 45 having a function to mechanically hold the backs of the piezoelectric elements 41 and further to attenuate an unnecessary ultrasonic signal when needed. The piezoelectric elements 41 are made of a piezoelectric ceramic such as PZT-based material, monocrystal or the like. The ground electrode 42 and the signal electrodes 43 are formed on the top surfaces and backs of the piezoelectric elements 41 in such a manner as to deposit or sputter gold or silver or to bake silver.

A difference between this embodiment and the first embodiment is that, as shown in FIGS. 9 and 10, the piezoelectric element 41 is made to have an approximately equal thickness T with respect to the minor-axis direction X and no division in the minor-axis direction X takes place. When the thickness T of the piezoelectric element 41 is made even, the transmission/reception of ultrasonic waves having frequencies approximately equal to each other is made in the minor-axis direction X. However, even in the case of the same frequency, by changing the width W of the piezoelectric element 41, the directivity can be changed in accordance with position in a direction perpendicular to the arraying direction of the piezoelectric elements 41. In FIG. 9, the width W of the piezoelectric element 41 is set to a minimum value Wmin at the central portion forming a position in the X-direction while the width thereof is made wider toward both the end portions, so the width W of the piezoelectric element 41 becomes a maximum value Wmax at both the end portions.

With this structure, the piezoelectric element 41 shows a minimum directivity at the central portion in the minor-axis direction X while it shows gradually higher characteristics toward both the end portions. This structure conducts the same operation as that of the piezoelectric element in the X-direction described above in the fifth embodiment and, although omitted, the electrical control is not implemented because no division is made in the minor-axis direction X of the piezoelectric element 41. Accordingly, in the minor-axis direction X of the piezoelectric element 41, the control of an ultrasonic beam is carried out at a small aperture in the vicinity of the central portion and, hence, an ultrasonic image with a high resolution is obtainable in a short-distance region.

Although in the description of the fifth embodiment nothing is located on the top surface of the ground electrode 42, the same effects are also obtainable even in the case of a structure of an ultrasonic probe in which one or more acoustic matching layers are formed thereon. Moreover, although in the description of the fifth embodiment a piezoelectric ceramics such as PZT or monocrystal is used as the piezoelectric elements 41, the same effects are also obtainable even in the case of a structure of an ultrasonic probe employing, as the piezoelectric elements 41, a so-called composite piezoelectric material produced by combining a piezoelectric ceramics and an organic polymer.

### Sixth Embodiment

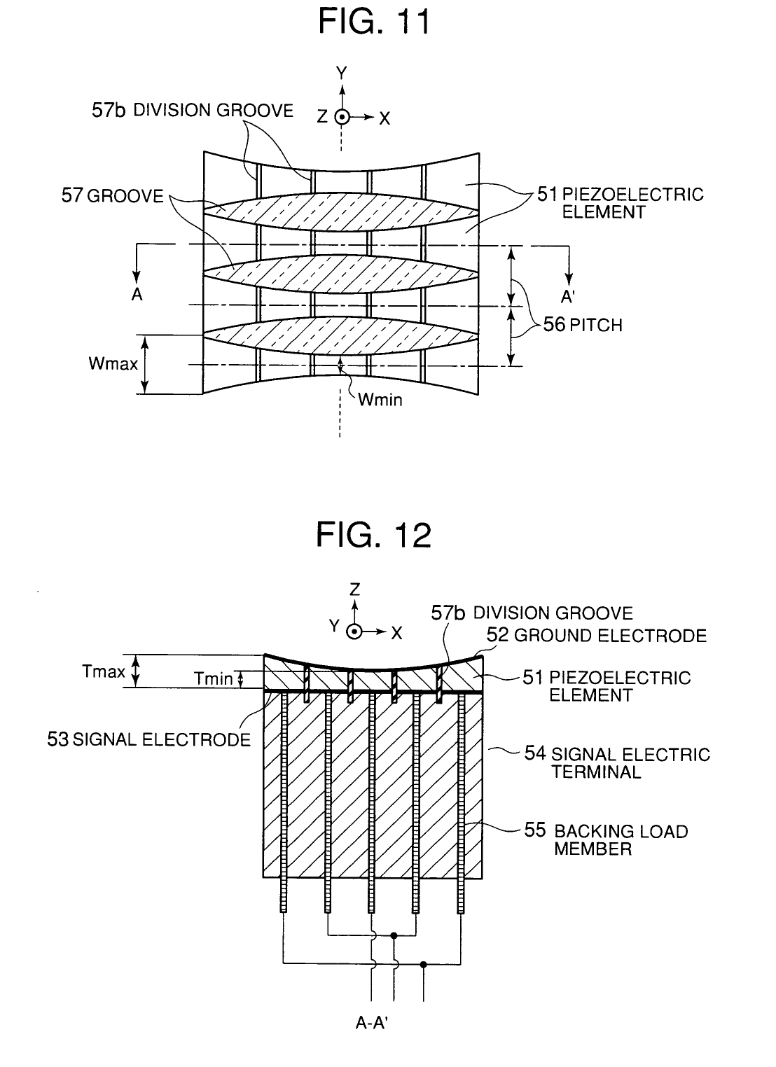

An ultrasonic probe according to an embodiment of the present invention will be described hereinbelow with reference to the drawings. An ultrasonic probe according to a sixth embodiment of the present invention is shown in FIGS. 11 and 12. FIG. 11 is a top view, and FIG. 12 is a side cross-sectional view taken along a lone A-A′ in FIG. 11.

In FIGS. 11 and 12, this ultrasonic probe is made up of a plurality of piezoelectric elements 51 arrayed in the Y-direction for transmission/reception of ultrasonic waves in the Z-direction and each divided by division grooves 57b, approximately parallel with each other along the Y-direction, into a plurality of sections in the X-direction, a common ground electrode 52 located on top surfaces of the piezoelectric elements 51, a plurality of signal electrodes 53 each provided on a back of each of the piezoelectric elements 51, a plurality of signal electric terminals 54 each for fetching a signal from each of the plurality of signal electrodes 53, and a backing load member 55 having a function to mechanically hold the backs of the piezoelectric elements 51 and further to attenuate an unnecessary ultrasonic signal when needed. The piezoelectric elements 51 are made of a piezoelectric ceramic such as PZT-based material, monocrystal or the like. The ground electrode 52 and the signal electrodes 53 are formed on the top surfaces and backs of the piezoelectric elements 51 in such a manner as to deposit or sputter gold or silver or to bake silver.

In FIG. 11, a pitch 56 between the piezoelectric elements 51 adjoining each other in the arraying direction Y is determined as needed. For example, in the case of a so-called phased array probe type made to electronically deflect an ultrasonic beam through phase control, the number of piezoelectric elements 51 to be arrayed is 64 to 128 and, in view of the occurrence angle of grating lobe, in general, the pitch 56 between the adjacent piezoelectric elements 51 is half a wavelength and, in a case in which the sound velocity of a medium like a living body is 1.54 km/s at a frequency of 2.5 MHz, the pitch 56 becomes 0.308 mm.

Moreover, each of grooves 57 is formed between the piezoelectric elements 51 adjacent to each other such that the width W of each of the piezoelectric elements 51 in the arraying direction Y shows a minimum value Wmin in the vicinity of a central portion forming a position in the piezoelectric element 51 in the X-direction, and it becomes gradually larger as the position shifts to each of both its end portions and has a maximum value Wmax at both the end portions thereof. When the width W of the piezoelectric element 51 in the arraying direction Y is made to show different values according to position therein in the X-direction (directivity setting means), the directivity becomes easily changeable.

Accordingly, contrary to the width W of the piezoelectric element 51, the width of the groove 57 formed between the adjoining piezoelectric elements 51 becomes wider in the vicinity of the central portion and it becomes narrower toward both the end portions. For making the adjoining piezoelectric elements 51 acoustically oscillate independently of each other, it is desirable that the groove 57 shows a large difference in acoustic impedance with respect to the piezoelectric element 51. Although a gas (air) is ideal, in view of stabilizing the piezoelectric element 51 and holding it against mechanical impacts, in fact the groove 57 are filled with a material such as silicone rubber or polyurethane rubber, or a material produced by mixing an inorganic material or a powder of an inorganic matter thereinto. Among available methods of making a structure so that the width W of the piezoelectric element 51 has different values according to position in the X-direction, there are a processing method based on a combination of laser beam and chemical etching and a processing method using sand blast or the like in a state where a patterned mask is put on the piezoelectric element 51.

In addition, in each of the piezoelectric elements 51, a plurality of division grooves 57b are formed in the direction X perpendicular to the arraying direction Y of the piezoelectric elements 51 to be in parallel with the arraying direction Y so that the piezoelectric element 51 is divided in the direction (hereinafter referred to equally as minor-axis direction) X perpendicular thereto. Although FIG. 11 shows a state divided into 5 sections, the number of divisions can be set according to purpose. In this connection, the ground electrode 52 can also be provided after the division grooves 57b are formed in the piezoelectric elements 51 and filled with a filler. Moreover, the signal electrodes 53, together with the piezoelectric elements 51, are divided by the division grooves 57b and, as shown in FIG. 12, the division is made such that the division grooves 57b have depths so as to reach a portion of the backing load member 55, and each of the signal electric terminals 54 is drawn from each of the divided signal electrodes 53. Although the connections to the signal electric terminals 54 after drawn depend upon purposes, shown here is a connection arrangement made with respect to the signal electric terminal 54 existing at a central portion. Such a structure is of a type of the plurality of piezoelectric elements 51 being two-dimensionally arrayed, which is referred to as a two-dimensional array.

FIG. 12 is a cross-sectional view taken along a line A-A′ in FIG. 11. The thickness T of the piezoelectric element 51 in the Z-direction is made to vary according to position in the X-direction and, in this example, the thickness T of the piezoelectric element 51 in the vicinity of its central portion is set at a minimum value (Tmin) while the thickness increases toward both the end portions so that it reaches a maximum value (Tmax) at both the end portions, thus forming a curved configuration. With respect to the minor-axis direction X of the plurality of piezoelectric elements 51 arranged in the Y-direction, the central portion at which the thickness T of the piezoelectric element 51 takes a minimum value can carry out the transmission/reception of a high frequency component, while, since the thickness of the piezoelectric element 51 increases toward both the end portions, the transmission/reception of a lower frequency component becomes feasible, thereby lengthening the depth of focus of an ultrasonic beam and providing a broadband frequency characteristic.

On the other hand, with respect to the plurality of piezoelectric elements 51 arrayed in the Y-direction, when each of the piezoelectric elements 51 is electronically delayed to carry out the phase control for deflecting an ultrasonic beam, the directivity of the piezoelectric element 51 greatly affects the performance. That is, in the case of the phase control, the degree of freedom of the phase control increases as the directivity of each of the piezoelectric elements 51 decreases and, hence, the lower directivity thereof is desirable. As commonly well-known, a directivity factor representative of this directivity is calculated according to the following equation.
Re(θ)=sin(π·a·sin θ/λ)/(π·a·sin θ/λ)
where a designates a width W of the piezoelectric element 51, and λ depicts a wavelength (sound velocity of a medium/frequency). As seen from the above-mentioned equation, the directivity factor Re(θ) tends to decrease as the width a of the piezoelectric element 51 becomes narrower, and it tends to increase as the frequency becomes higher.

This ultrasonic probe 51 is made such that, when an electric signal is applied from a main body of ultrasonic diagnostic equipment or the like through the signal electric terminals 54 and the ground electric terminal (not shown) drawn from the ground electrode 52, the piezoelectric elements 51 mechanically oscillate so as to make the transmission and reception of ultrasonic waves. An ultrasonic probe for use in ultrasonic diagnostic equipment handling a living body as an object under inspection is a so-called sensor to be directly brought into contact with a living body or indirectly brought into contact therewith in a state where an ultrasonic wave propagation medium is interposed therebetween, so as to transmit ultrasonic waves into the living body and to again receive waves reflected from the living body so that the main body processes this signal and displays a diagnostic image on a monitor for diagnosis.

In this system, in general, the transmission/reception in each of the plurality of piezoelectric elements 51 arrayed in the Y-direction is time-delayed so as to implement the phase control so that an ultrasonic beam is focused at a desired position for achieving a high resolution, or an ultrasonic beam is deflected to carry out sector-like scanning. For example, in the structure shown in FIGS. 11 and 12, in a case in which piezoelectric ceramics corresponding to PZT-5H is used as the piezoelectric elements 51 to set the mean frequency of both the end portions at 2.5 MHz and set the mean frequency of the central portion at 5 MHz, with respect to the thickness T of the piezoelectric element 51, the central portion has a thickness of Tmin=approximately 0.3 mm, while the thickness T thereof becomes gradually larger toward both the end portions so that both the end portions have a thickness of Tmax=approximately 0.6 mm.

On the other hand, with respect to the arraying direction Y, as mentioned above, when the pitch 56 is set on the basis of half the wavelength, because of the frequency=5 MHz, the width Wmin of the central portion of the piezoelectric element 51 becomes ½ of 1 wavelength (0.308 mm), i.e., Wmin=0.154 mm. The width of the piezoelectric element 51 increases gradually and continuously with respect to the width Wmin (curved configuration) toward both the end portions and the width Wmax reaches 0.308 mm at both the end portions because of the frequency=2.5 MHz. In the case of this structure, even if the frequency varies from the central portion to both the end portions, as the directivity according to position in the piezoelectric element 51 in the X-direction, the width W of the piezoelectric element 51 in the arraying direction Y takes a different value according to the position in the X-direction and, hence, the desired directional characteristics approximately equal to each other are securable at the central portion and at both the end portions.

In addition, according to purpose, the directional characteristic can be changed according to position in the X-direction by properly changing the width W of the piezoelectric elements 51, arrayed in the arraying direction Y, in the X-direction. Still additionally, a high frequency of the piezoelectric element 51 in the vicinity of its central portion forming a position in the X-direction tends to show a short distance (position where the depth is near field) in an ultrasonic image and a lower directivity is desirable. For this reason, the width Wmin of the central portion is further decreased, which enables the central portion to have a lower directivity than that of both the end portions. Therefore, even a portion having a high frequency component in the vicinity of the central portion of the piezoelectric element 51 can be lowered in directivity, which permits the phase control to be freely executed through the use of many piezoelectric elements 51 arrayed and enables narrowing an ultrasonic beam down and deflecting an ultrasonic beam, thus providing an ultrasonic probe which can produce an ultrasonic image with a high resolution.

Incidentally, although in the description of the sixth embodiment nothing is provided on the ground electrode 52 positioned on the top surface side of the piezoelectric element 51, the same effects are also attainable even in the case of a structure of an ultrasonic probe in which one or more acoustic matching layers are formed on the top surface of the ground electrode 52. Moreover, although in the description of the sixth embodiment a piezoelectric ceramics such as PZT or monocrystal is used as the piezoelectric elements 51, a structure of an ultrasonic probe employing, as the piezoelectric elements 51, a so-called composite piezoelectric material produced by combining a piezoelectric ceramics and an organic polymer can also provide the same effects.

### Seventh Embodiment

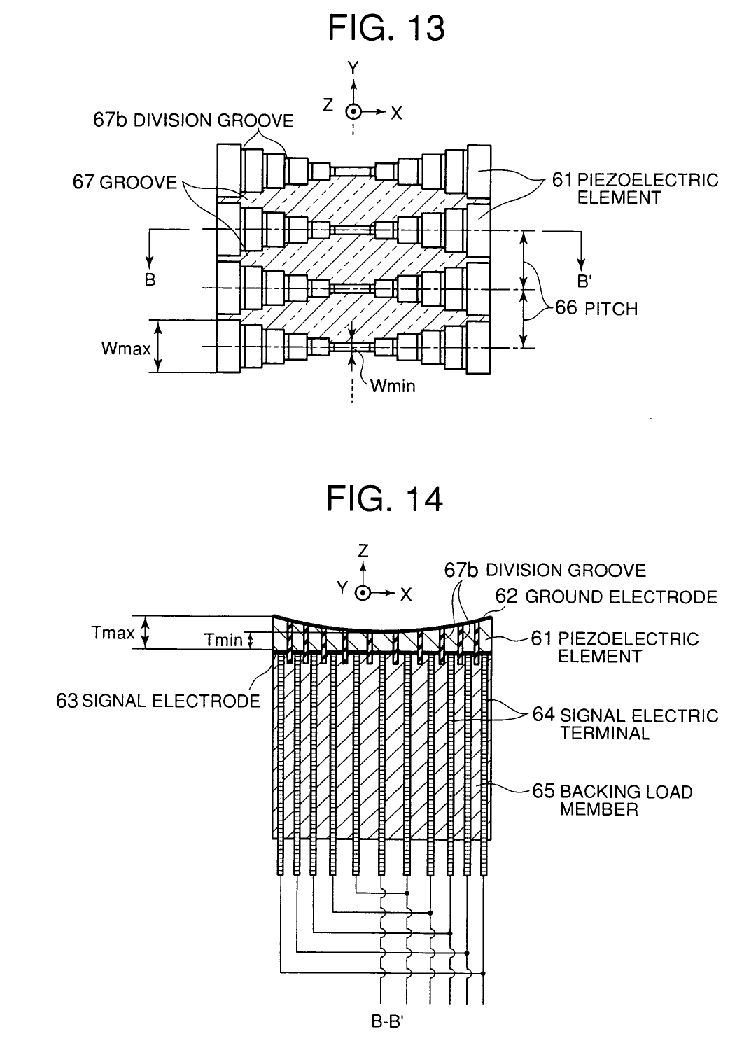

An ultrasonic probe according to a seventh embodiment of the present invention is shown in FIGS. 13 and 14. In FIGS. 13 and 14, this ultrasonic probe is made up of a plurality of piezoelectric elements 61 arrayed in the Y-direction for transmission/reception of ultrasonic waves in the Z-direction and each divided into a plurality of sections in the X-direction, a common ground electrode 62 located on top surfaces of the piezoelectric elements 61, a plurality of signal electrodes 63 each provided on a back of each of the piezoelectric elements 61, a plurality of signal electric terminals 64 each for fetching a signal from each of the plurality of signal electrodes 63, and a backing load member 65 having a function to mechanically hold the backs of the piezoelectric elements 61 and further to attenuate an unnecessary ultrasonic signal when needed. The piezoelectric elements 61 are made of a piezoelectric ceramic such as PZT-based material, monocrystal or the like. The ground electrode 62 and the signal electrodes 63 are formed on the top surfaces and backs of the piezoelectric elements 61 in such a manner as to deposit or sputter gold or silver or to bake silver.

In addition, in FIG. 13, a pitch 66 between the piezoelectric elements 61 adjacent to each other in the Y-direction is determined as needed as in the case of the sixth embodiment. For example, in the case of a so-called phased array probe type made to electronically deflect an ultrasonic beam through phase control, the number of piezoelectric elements 61 to be arrayed is commonly 64 to 128, and the pitch 66 is half a wavelength and, in a case in which the sound velocity of a medium is 1.54 km/s at a frequency of 2.5 MHz, the pitch 66 becomes 0.308 mm. Still additionally, the width W of the piezoelectric elements 61 is made to have a minimum width Wmin in the vicinity of the central portion forming a position in the X-direction, while it increases stepwise toward both the end portions, so the width W of both the end portions is set at a maximum value Wmax.

Furthermore, in each of the piezoelectric elements 61, a plurality of division grooves 67b are formed in the minor-axis direction X to divide the piezoelectric element 61 in the minor-axis direction. The width W of the piezoelectric element 61 in the minor-axis direction varies stepwise from the width Wmin to the width Wmax, and the division is made by the division groove 67b at every variation of the width W of the piezoelectric element 61. This point differs from the sixth embodiment. Although FIGS. 13 and 14 show 11 divisions, the number of divisions can be set according to purpose. Incidentally, the ground electrode 62 can also be provided after the division grooves 67b are formed in the piezoelectric elements 61 and filled with a filler. Moreover, the signal electrodes 63, together with the piezoelectric elements 61, are divided by the division grooves 67b and, as shown in FIG. 14, the division is made such that the division grooves 67b have depths so as to reach a portion of the backing load member 65, and each of the signal electric terminals 64 is drawn from each of the divided signal electrodes 63. Although the connections to the signal electric terminals 64 after drawn depend upon purposes, shown here is a connection arrangement made symmetrically with respect to the signal electric terminal 64 existing at a central portion. Such a structure is of a type of the plurality of piezoelectric elements 61 being two-dimensionally arrayed, which is referred to as a two-dimensional array.

FIG. 14 is a cross-sectional view taken along a line B-B′ in FIG. 13. The thickness T of the piezoelectric element 61 in the Z-direction is made to vary according to position in the X-direction and, in this example, as a configuration, the thickness T of the piezoelectric element 61 in the vicinity of its central portion is set at a minimum value Tmin while the thickness T increases toward both the end portions so that it reaches a maximum value Tmax at both the end portions. The thickness T of the piezoelectric element 61 can be made to vary continuously or it can also be made to vary stepwise. With respect to the minor-axis direction X of the piezoelectric elements 61, the central portion at which the thickness T of the piezoelectric element 61 takes a minimum value can carry out the transmission/reception of a high frequency component, while, since the thickness of the piezoelectric element increases toward both the end portions, the transmission/reception of a lower frequency component becomes feasible, thereby lengthening the depth of focus of an ultrasonic beam and providing a broadband frequency characteristic.

On the other hand, as described in the sixth embodiment, with respect to the piezoelectric elements 61 arrayed in the Y-direction, when each of the piezoelectric elements 61 is electronically delayed to carry out the phase control for deflecting an ultrasonic beam, the directivity of the piezoelectric element 61 greatly affects the performance. That is, in the case of the phase control, the degree of freedom of the phase control preferably increases as the directivity of each of the piezoelectric elements 61 decreases. These operations of the ultrasonic probe are the same as those described in the sixth embodiment, and the description thereof will be omitted.

For example, in the structure shown in FIGS. 13 and 14, in a case in which piezoelectric ceramics corresponding to PZT-5H is used as the piezoelectric elements 61 to set the mean frequency of both the end portions at 2.5 MHz and set the mean frequency of the central portion at 5 MHz, as the thickness T of the piezoelectric element 61, the central portion has a thickness of Tmin=approximately 0.3 mm, while the thickness T thereof becomes gradually larger so that both the end portions have a thickness of Tmax=approximately 0.6 mm. On the other hand, with respect to the arraying direction Y, when the array pitch 66 is basically set at half the wavelength as mentioned above, because of 5 MHz, the minimum width Wmin of the piezoelectric element 61 at its central portion becomes half as much as one wavelength=0.308, i.e., Wmin=0.154 mm.

As the position shifts from the portion having this width Wmin to both the end portions, for example, the frequency is symmetrically divided into 6 stages on one side (11 divisions in total at both sides) so that the width W of the piezoelectric element 61 becomes stepwise larger. Therefore, in a case in which the high frequency at the central portion is set at 5 MHz and the next frequencies are set at 4.5 MHz, 4 MHz, 3.5 MHz, 3 MHz and the frequency at both the end portions is set at 2.5 MHz, respectively, while the respective widths W are set at half the wavelength, the width W becomes 0.154 mm at 5 MHz, 0.171 mm at 4.5 MHz, 0.193 mm at 4 MHz, 0.22 mm at 3.5 MHz and 0.257 mm at 3 MHz, and both the end portions have a maximum width, i.e., Wmax=0.308 mm at 2.5 MHz.

With this structure, even if the frequency stepwise varies as the position in the X-direction shifts from the central portion to both the end portions, since the width W of the piezoelectric element 61 varies, with respect to the directivity according to the position in the piezoelectric element 61 in the X-direction, the directional characteristics approximately equal to each other are securable. Therefore, since even a portion with a high frequency in the vicinity of the central portion of the piezoelectric element 11 can be lowered in directivity, it is possible to carry out the phase control freely through the use of many piezoelectric elements 61 arrayed and to narrow down and deflect an ultrasonic beam, thus providing an ultrasonic probe which can produce an ultrasonic image with a high resolution.

Although in the description of the seventh embodiment nothing is provided on a top surface of the ground electrode 62, the same effects are also obtainable even in the case of a structure of an ultrasonic probe in which one or more acoustic matching layers are formed on the top surface of the ground electrode 62. Moreover, although in the description of the seventh embodiment a piezoelectric ceramics such as PZT or monocrystal is used as the piezoelectric elements 61, the same effects are also obtainable even in the case of a structure of an ultrasonic probe employing, as the piezoelectric elements 61, a so-called composite piezoelectric material produced by combining a piezoelectric ceramics and an organic polymer.

The stepwise change of the width W of the piezoelectric element 61 is more advantageous in manufacturing and cost than the continuous change of the width W thereof. Ideally, it is desirable that these steps are processed more finely to make a continuously varying type superior in performance.

### Eighth Embodiment

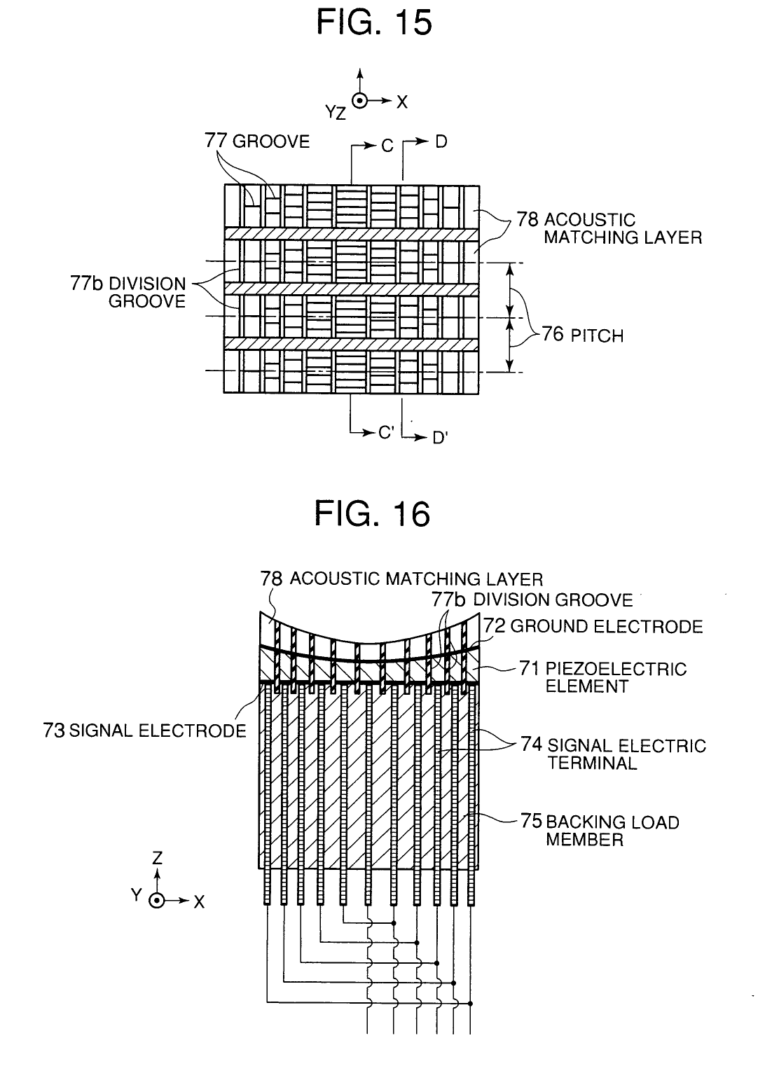

FIGS. 15 to 18 are illustrations of an ultrasonic probe according to an eighth embodiment of the present invention. This ultrasonic probe is made up of a plurality of piezoelectric elements 71 arrayed in the Y-direction for transmission/reception of ultrasonic waves in the Z-direction and each divided into a plurality of sections in the X-direction, a common ground electrode 72 located on top surfaces of the piezoelectric elements 71, acoustic matching layers 78 each formed as a one-or-more-layer structure (in this case, acoustic matching layers each formed as one layer), a plurality of signal electrodes 73 each provided on a back of each of the piezoelectric elements 71, a plurality of signal electric terminals 74 each for fetching a signal from each of the signal electrodes 73, and a backing load member 75 having a function to mechanically hold the backs of the piezoelectric elements 71 and further to attenuate an unnecessary ultrasonic signal when needed. The piezoelectric elements 71 are made of a piezoelectric ceramic such as PZT-based material, monocrystal or the like. The ground electrode 72 and the signal electrodes 73 are formed on the top surfaces and backs of the piezoelectric elements 71 in such a manner as to deposit or sputter gold or silver or to bake silver.

As FIG. 15 shows, with respect to the minor-axis direction X of the piezoelectric elements 71 and the acoustic matching layers 78, although the width W does not vary unlike the sixth and seventh embodiments, the structure in the minor-axis direction X differs from the sixth and seventh embodiments. That is, each of the piezoelectric elements 71 and each of the acoustic matching layers 78 are divided by a plurality of division grooves 77b in the minor-axis direction X. The number of divisions stands at 11, but it can properly be determined according to purpose. Each of the signal electric terminals 74 is drawn from the signal electrode 73 divided as well as the piezoelectric element 71. On the other hand, as shown in FIG. 15, in the acoustic matching layer 78, its central portion in the minor-axis direction X is divided into 6 sections by grooves 77 in the arraying direction Y, and the number of divisions is stepwise decreased toward both the end portions.

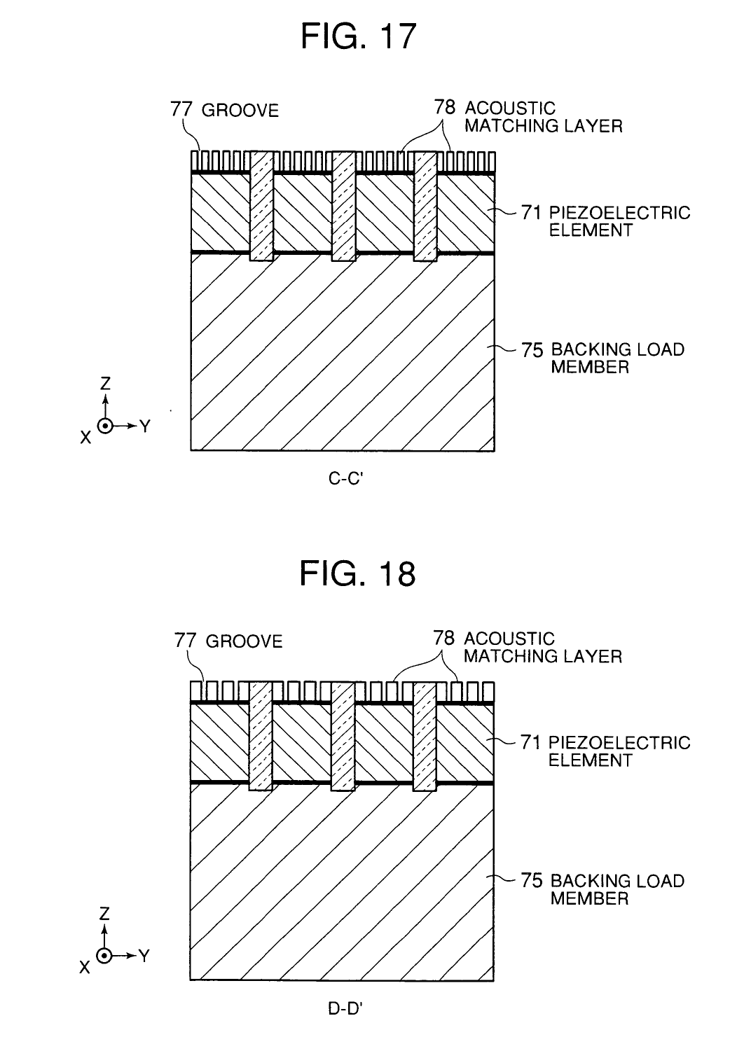

FIGS. 17 and 18 are cross-sectional views taken along lines C-C′ and D-D′ in FIG. 15, respectively, for explaining a structure of the grooves 77 of the acoustic matching layer 78. FIG. 17 shows a central portion where the acoustic matching layer 78 is divided into 6 sections, and FIG. 18 shows a next-but-one portion with respect to the central portion, where it is divided into 4 sections. Although it is most desirable that the interiors of these grooves 77 of the acoustic matching layer 78 are filled with air, if this makes it difficult to construct the ultrasonic probe, it is also acceptable to use a soft resin, for example, silicone rubber or polyurethane rubber, or a material produced by mixing a powder of an inorganic matter or the like thereinto. In this connection, it is also appropriate that the grooves 77 to be made in the acoustic matching layer 78 are additionally made in a portion of each of the piezoelectric elements 71.

With the structure described above, when the transmission/reception of ultrasonic waves is made at a high frequency at the central portion forming a position in the piezoelectric element 71 in the X-direction and made at a lower frequency toward both the end portions, although the widths of the piezoelectric element 71 in the minor-axis direction X are equal to each other, the directivity is lowered because the number of divisions of the acoustic matching layer 78 is further increased at a portion generating a higher frequency. This utilizes the fact that, without the division of the piezoelectric element 71, the directivity can be lowered by dividing the acoustic matching layer 78 by means of a laser beam or an ultrasonic cutter. Therefore, this can solve a problem that a difference in directional characteristic exists between the central portion and both the end portions which form positions in the X-direction and the central portion has a higher directional characteristic.

That is, looking at the fact that the directional characteristic of the ultrasonic probe has relation to the width of the piezoelectric element 71 and the width of the acoustic matching layer 78 or the number of divisions, the number of divisions of the acoustic matching layer 78 in the Y-direction is increased toward the center of the position in the X-direction so as to approach the point sound source, thereby lowering the directivity. In this embodiment, the central portion has a high directivity because it shows a high frequency and, for lowering this, the number of divisions at the central portion forming a position in the acoustic matching layer 78 in the X-direction is set at a maximum while the number of divisions of the acoustic matching layer 78 is stepwise decreased toward both the end portions, thereby attaining the directional characteristics nearly equal to each other. In addition, since the piezoelectric element 71 and the acoustic matching layer 78 are divided in the minor-axis direction X and the signal electric terminals 74 are drawn therefrom, an ultrasonic bean is controllable through electrical switching or phase control.

Thus, since even a portion with a high frequency component in the vicinity of the positional center of the piezoelectric element 71 in the X-direction can be lowered in directivity, the phase control is freely executable through the use of many piezoelectric elements 71 arrayed and an ultrasonic beam can be narrowed down and deflected, which provides an ultrasonic probe which can produce an ultrasonic image with a high resolution.

Moreover, although in the description of the eighth embodiment a piezoelectric ceramics such as PZT or monocrystal is used as the piezoelectric elements 71, a structure of an ultrasonic probe employing, as the piezoelectric elements 71, a so-called composite piezoelectric material produced by combining a piezoelectric ceramics and an organic polymer can also provide the same effects. Still moreover, although in the description of the eighth embodiment the widths W of the piezoelectric element 71 in the arraying direction Y are made to be nearly equal to each other in the X-direction, the same effects are obtainable even in the case of a structure of an ultrasonic probe in which the width is made narrower at the central portion forming a position in the X-direction and is made wider toward both the end portions or in which a so-called composite piezoelectric material produced by combining a piezoelectric ceramics and an organic polymer is employed as the piezoelectric elements 71.

### Ninth Embodiment

Referring to FIGS. 11 and 12, a description will be given hereinbelow of an ultrasonic probe according to a ninth embodiment of the present invention. The structure according to the ninth embodiment is the same as that according to the sixth embodiment, and the description there of will be omitted. Therefore, the description will be given of only the functions and operations of the ninth embodiment. Each of the piezoelectric elements 51 is divided in the minor-axis direction X through the use of a plurality of division grooves 57b. Although FIG. 11 shows a state divided into 5 sections, the number of divisions can be set according to purpose. The division grooves 57b of the piezoelectric elements 51 can be easily formed by means of machining using a dicing machine or the like. Incidentally, the ground electrode 52 can be provided after the division grooves 57b are made in the piezoelectric elements 51 and filled with a filler.

Moreover, the signal electrodes 53, together with the piezoelectric elements 51, are divided by the division grooves 57b and, as shown in FIG. 12, the division is made such that the division grooves 57b have depths so as to reach a portion of the backing load member 55, and each of the signal electric terminals 54 is drawn from each of the divided signal electrodes 53. Although the connections to the signal electric terminals 54 after drawn depend upon purposes, shown here is a connection arrangement made symmetrically with respect to the signal electric terminal 54 existing at a central portion. Such a structure is of a type of the plurality of piezoelectric elements 51 being two-dimensionally arrayed, which is referred to as a two-dimensional array.

Moreover, as shown in FIG. 12, as a configuration, the thickness T of the piezoelectric element 51 varies according to position in the X-direction so that the thickness T of the piezoelectric element 51 in the vicinity of the central portion takes a minimum value Tmin while the thickness increases as the position shifts to both the end portions and reaches Tmax at both the end portions. Thus, with respect to the minor-axis direction X of the plurality of piezoelectric elements 51 arranged the central portion at which the thickness T of the piezoelectric element 51 stands at a minimum value can carry out the transmission/reception of a high frequency component, while, since the thickness of the piezoelectric element 51 increases toward both the end portions, the transmission/reception of a lower frequency component becomes feasible, thereby lengthening the depth of focus of an ultrasonic beam and providing a broadband frequency characteristic. On the other hand, since the width W of the piezoelectric element 51 varies from Wmin to Wmax in the X-direction in conjunction with the respective frequencies, the directivity according to position in the X-direction can be changed according to place, or similar characteristics are obtainable.

In the ninth embodiment, in a case in which the thickness Tmin to Tmax of the piezoelectric element 51 and the width Wmin to Wmax take continuously different values, the ratio W/T of the width W of the piezoelectric element 51 and the thickness T thereof varies. On the other hand, the W/T of the piezoelectric element 51 is already well-known and, as an electromechanical coupling coefficient k of the piezoelectric element 51 becomes higher, the sensitivity increases, and the specific frequency band can be widened. This has great relation to the W/T and, in the case of a piezoelectric ceramic material corresponding to PZT-5H, the electromechanical coupling coefficient k shows a maximum value when the W/T is close to 0.5 to 0.6.

Accordingly, since the thickness T is at a minimum in the vicinity of the central portion forming a position in the piezoelectric element 51 in the X-direction, it is desirable that, in connection with this thickness, the width W is set so that the W/T becomes 0.5 to 0.6. Moreover, since the thickness T of the piezoelectric element 51 increases toward both the end portions, it is desirable that the width W is gradually made wider so that the W/T falls into a range of 0.5 to 0.6 as a value within a predetermined range. Thus, the electromechanical coupling coefficient k becomes the same in any region, which provides an excellent characteristic (frequency characteristic, sensitivity). Moreover, for a type in which the thickness T of the piezoelectric element 51 is changed in the direction X perpendicular to the arraying direction Y so as to change the frequency, if the width W of the piezoelectric element 51 is equalized from the central portion to both the end portions, the W/T at the central portion forming a thin portion of the piezoelectric element 51 becomes higher. When the W/T exceeds 0.6, the oscillation occurs even in the width direction Y and, when the frequency thereof approaches the oscillation frequency in the thickness direction Z, adverse effects appear on the frequency characteristic. This embodiment is made to reduce the adverse influence of the oscillation frequency in the width direction Y.

With the structure described above, since not only even a portion with a high frequency component in the vicinity of the central portion forming a position in the piezoelectric element 51 in the X-direction can be lowered in directivity but also the electromechanical coupling coefficient k of the piezoelectric element 51 shows a high value and even the influence of the frequency of the width oscillation is reducible, a broad frequency band is obtainable together with a high sensitivity and an ultrasonic beam can be narrowed down, which can provide an ultrasonic probe capable of producing an ultrasonic image with a high resolution. In addition, since the piezoelectric element 51 is divided in the minor-axis direction and each of the signal electric terminals 54 is drawn from each of the divided piezoelectric elements 51, the transmission/reception of ultrasonic waves by the piezoelectric element 51 can also be changed through electrical switching, which can provide an ultrasonic probe capable of producing an ultrasonic image with a higher resolution.

Although in the description of the ninth embodiment the thickness Tmin to Tmax of the piezoelectric element 51 and the width Wmin to Wmax thereof vary continuously, also in a case in which both the thickness Tmin to Tmax of the piezoelectric element 51 and the width Wmin to Wmax thereof are made to vary stepwise, or even when only the thickness T or only the width W is made to vary stepwise, the same effects are attainable.

### Tenth Embodiment

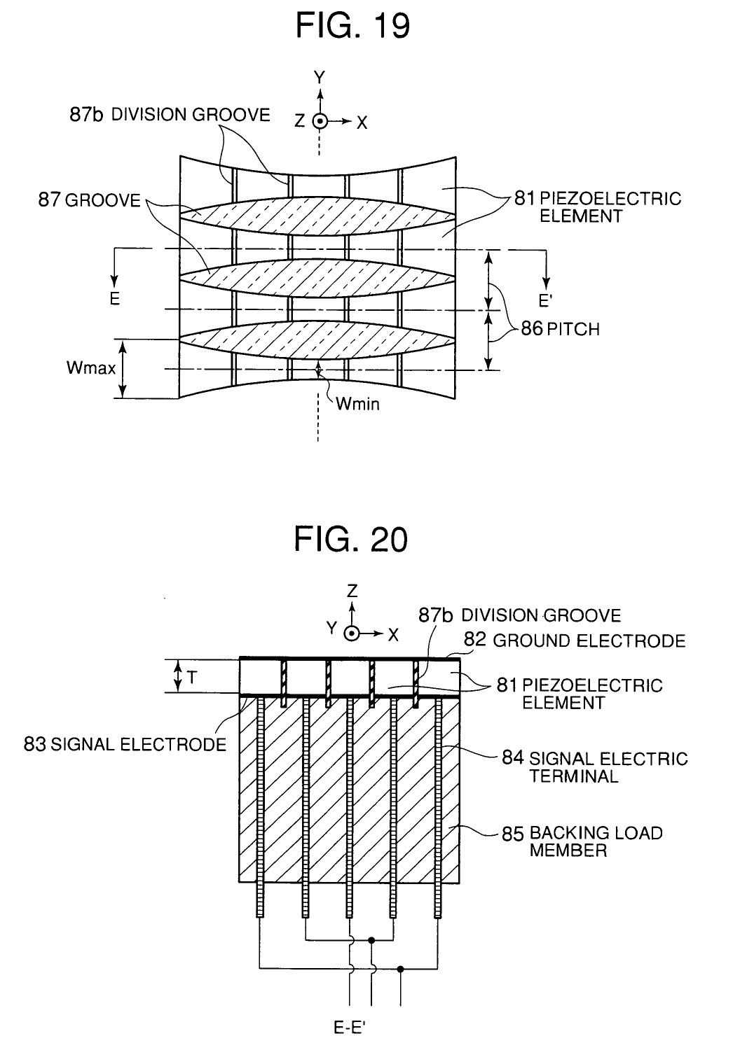

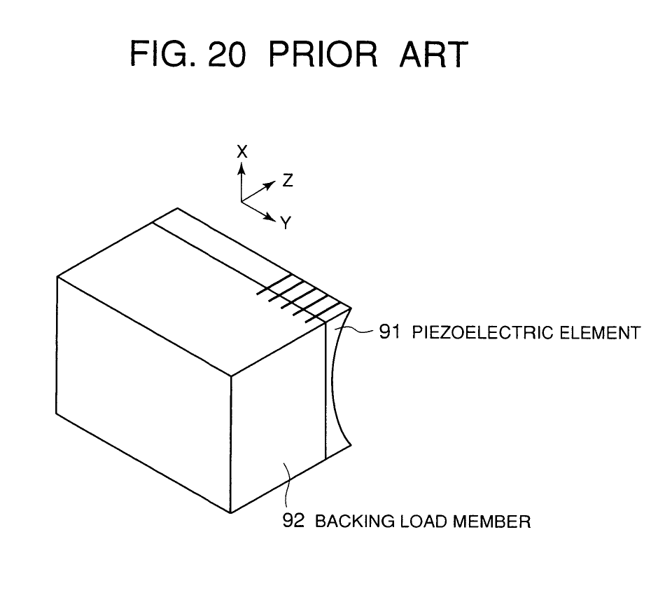

An ultrasonic probe according to a tenth embodiment of the present invention is shown in FIGS. 19 and 20. In FIGS. 19 and 20, this ultrasonic probe is made up of a plurality of piezoelectric elements 81 arrayed in the Y-direction for transmission/reception of ultrasonic waves in the Z-direction and each divided into a plurality of sections in the X-direction, a common ground electrode 82 located on top surfaces of the piezoelectric elements 81, a plurality of signal electrodes 83 each provided on a back of each of the piezoelectric elements 81, a plurality of signal electric terminals 84 each for fetching a signal from each of the plurality of signal electrodes 83, and a backing load member 85 having a function to mechanically hold the backs of the piezoelectric elements 81 and further to attenuate an unnecessary ultrasonic signal when needed. The piezoelectric elements 81 are made of a piezoelectric ceramic such as PZT-based material, monocrystal or the like. The ground electrode 82 and the signal electrodes 83 are formed on the top surfaces and backs of the piezoelectric elements 81 in such a manner as to deposit or sputter gold or silver or to bake silver.

In FIG. 19, a pitch 86 between the piezoelectric elements 81 is determined as needed. As in the case of the sixth embodiment, groove 87 of the piezoelectric elements 81 arrayed is filled with a material such as silicone rubber or polyurethane rubber, or a material produced by mixing an inorganic material or a powder of an inorganic matter thereinto. In addition, each of the piezoelectric elements 81 is divided by division grooves 87b (in this case, divided into 5 sections) in the minor-axis direction X and, as well as the piezoelectric elements 81, the signal electrode 83 is divided in the X-direction, and each of the signal electric terminals 84 is drawn from each of the divided signal electrodes 83.

A difference between this embodiment and the sixth embodiment is that, as shown in FIG. 20, the piezoelectric element 81 has thickness T approximately equal to each other in the minor-axis direction. The equalization of the thickness T of the piezoelectric element 81 signifies that the transmission/reception of ultrasonic waves with almost same frequencies is made at the respective positions in the minor-axis direction X and, even in the case of the same frequencies, by changing the width W of the piezoelectric element 81, the directivity can be changed in accordance with position in the piezoelectric element 81 in the X-direction. In FIG. 19, the width W of the piezoelectric element 81 is set to a minimum value Wmin at its central portion forming a position in the X-direction while it is made wider toward both the end portions so as to take a maximum value Wmax at both the end portions.

With this structure, as a characteristic on the directivity according to position in the piezoelectric element 81 in the minor-axis direction X, the central portion shows a lowest directivity while the directivity gradually increases toward both the end portions. On the other hand, an ultrasonic beam under electronic delay control in the arraying direction Y of the piezoelectric elements 81 can be narrowed down at an arbitrary distance (depth) and, although in a region distant (deep) from the piezoelectric element 81 the ultrasonic beam can be narrowed down even in a case in which the directivity is not very low, in the case of a short distance, the directivity has a great influence and, hence, the degree of narrowing-down of the ultrasonic beam varies, so a characteristic low in directivity is desirable. In this embodiment, the directivity in the vicinity of the central portion forming a position of the piezoelectric element 81 in the minor-axis direction shows a lowest value, and this contributes most greatly to the narrowing-down of an ultrasonic beam at a short distance through electronic control and the degree of contribution decreases toward both the end portions, Therefore, with respect to position in the minor-axis direction X of the piezoelectric element 81, the control of an ultrasonic beam is carried out at a small aperture in the vicinity of the central portion and, hence, an ultrasonic image with a high resolution is obtainable in a short-distance region.

Moreover, although in the description of the tenth embodiment nothing is provided on the ground electrode 82, the same effects are also attainable even in the case of a structure of an ultrasonic probe in which one or more acoustic matching layers are formed on the top surface of the ground electrode 82. Still moreover, although in the description of the tenth embodiment a piezoelectric ceramics such as PZT or monocrystal is used as the piezoelectric elements 81, a structure of an ultrasonic probe employing, as the piezoelectric elements 81, a so-called composite piezoelectric material produced by combining a piezoelectric ceramics and an organic polymer can also provide the same effects.

### INDUSTRIAL APPLICABILITY

Ultrasonic probes according to the present invention are applicable to ultrasonic diagnosis and inspection for medial care and others because they can provide an ultrasonic image with a high resolution.

1. An ultrasonic probe comprising:
a plurality of piezoelectric elements arrayed in one direction for transmission and reception of ultrasonic waves; and
directivity setting means for setting different ultrasonic wave directivities according to position in a direction perpendicular to the arraying direction of said piezoelectric elements.

2. The ultrasonic probe according to claim 1, further comprising division grooves for dividing each of said piezoelectric elements into a plurality of sections so that the divided sections are disposed side by side to stand in line along the direction perpendicular thereto.

3. The ultrasonic probe according to claim 1, wherein said directivity setting means is made such that a width of each of said piezoelectric elements in the arraying direction is made to have a minimum value at a central portion forming a position in the direction perpendicular thereto and is made to increase toward both end portions thereof.

4. The ultrasonic probe according to claim 3, wherein the width of each of said piezoelectric elements is made to increase continuously as a position in the direction perpendicular thereto shifts from said central portion to both said end portions.

5. The ultrasonic probe according to claim 3, wherein
the width of each of said piezoelectric elements is made to increase stepwise as a position in the direction perpendicular thereto shifts from said central portion to both said end portions.

6. The ultrasonic probe according to claim 1, wherein one or more acoustic matching layers are formed on each of said piezoelectric elements, and said directivity setting means is made such that the number of divisions made in said acoustic matching layer in the arraying direction stands at a maximum at its central portion forming a position in the direction perpendicular thereto and the number of divisions in the arraying direction decreases as the position in the direction perpendicular thereto shifts to both said end portions.

7. The ultrasonic probe according to claim 1, wherein a thickness T of each of said piezoelectric elements varies according to position in the direction perpendicular thereto, and said directivity setting means is made such that a ratio W/T between a width W of said piezoelectric element and a thickness T thereof falls within a predetermined range as the position in the direction perpendicular thereto shifts from said central portion to both said end portions.

8. The ultrasonic probe according to claim 6, wherein the ratio W/T between said width W and said thickness T continuously or stepwise falls within said predetermined range as the position in the direction perpendicular thereto shifts from said central portion to both said end portions.

9. The ultrasonic probe according to claim 1, wherein the thickness of each of said plurality of piezoelectric elements is made equally irrespective of position in the direction perpendicular thereto.

10. The ultrasonic probe according to claim 1, wherein said directivity setting means is designed such that a directivity of the ultrasonic probe is set at the lowest directivity at said central portion which forms a position in the direction perpendicular thereto while it is set to become higher as the position in the direction perpendicular thereto shifts to both said end portions thereof.

11. The ultrasonic probe according to claim 1, wherein a transmission/reception frequency of said piezoelectric elements is set at the highest frequency at said central portion which forms a position in the direction perpendicular thereto while it is set to become lower as the position in the direction perpendicular thereto shifts to both said end portions.
